(19) United States
(12) Patent Application Publication
(10) Pub. No.: US 2013/0300261 A1
(43) Pub. Date: Nov. 14, 2013

(54) PIEZOELECTRIC VIBRATION MODULE

(71) Applicant: SAMSUNG ELECTRO-MECHANICS CO., LTD., Gyunggi-do (KR)

(72) Inventors: Jae Kyung Kim, Gyunggi-do (KR); Dong Sun Park, Gyunggi-do (KR); Joon Choi, Gyunggi-do (KR); Yeon Ho Son, Gyunggi-do (KR)

(73) Assignee: Samsung Electro-Mechanics Co., LTD., Gyunggi-do (KR)

(21) Appl. No.: 13/663,363

(22) Filed: Oct. 29, 2012

(30) Foreign Application Priority Data
May 8, 2012 (KR) 10-2012-0048710

(51) Int. Cl. H01L 41/053

(52) U.S. Cl. 310/348

(57) ABSTRACT

Disclosed herein is a piezoelectric vibration module in which piezoelectric elements generating vibration force by repetitively extending and being shrinkingly deformed through application of flat external power are placed symmetrically around the center of a lower plate of a vibration plate.

### CROSS REFERENCE TO RELATED APPLICATION

This application claims the benefit of Korean Patent Application No. 10-2012-0048710, filed on May 8, 2012, entitled “Piezoe Vibration Module”, which is hereby incorporated by reference in its entirety into this application.

### BACKGROUND OF THE INVENTION

1. Technical Field

The present invention relates to a piezoelectric vibration module.

2. Description of the Related Art

In general, in portable electronic apparatuses such as a cellular phone, an electronic book (E-book) terminal, a game machine, a PMP, and the like, a vibration function is used for various purposes.

In particular, a vibration generator for generating vibration is primarily mounted on the portable electronic apparatuses to be used as a warning function which is a silent receiving signal.

Due to implementation of multi-functions of the portable electronic apparatuses, the vibration generator actually requires miniaturization, integration, and various high-functionality at present.

Furthermore, a touch type device has been generally adopted, which performs an input operation by touching the portable electronic apparatus according to a user's request to intend to conveniently use the portable electronic apparatus.

A haptic device which is currently in common use widely includes even a concept of reflecting interface user's intuitive experience and further diversifying a feedback for a touch in addition to a concept of performing an input operation through the touch. The haptic device is disclosed in Patent Document 1.

An actuator module, a haptic feedback device, and an electronic apparatus disclosed in Patent Document 1 include one or more piezoelectric elements and a vibration plate mounted with the piezoelectric elements to transfer vibration generated from the piezoelectric elements.

The actuator module contacts one surface of the vibration plate in the longitudinal direction to vibrate the vibration plate vertically through the piezoelectric element of which the volume varies depending on an electric signal.

The actuator module according to Patent Document 1 is mounted on one surface of the vibration plate in the longitudinal direction as described above, in which for example, two piezoelectric elements are placed in parallel in the longitudinal direction of the vibration plate.

In order to mount two piezoelectric elements that are placed in parallel (in other words, arranged in parallel) on the vibration plate in the related art, the width of the vibration plate need to be increased, and as a result, an occupancy space inside a portable electronic apparatus cannot but be increased. This is contrary to a piezoelectric actuator module gradually requiring miniaturization and integration.

Moreover, the piezoelectric element has a bar shape in which the length is larger than the width, and as a result, the piezoelectric element cannot but have vulnerability and since the piezoelectric element continuously extends and shrinks in repetition, the piezoelectric element is easily broken, thereby deteriorating reliability.

### PRIOR ART DOCUMENT

### Patent Document

(Patent Document 1) Patent Document 1: Korean Patent Laid-Open Publication No. 10-2011-0118079

### SUMMARY OF THE INVENTION

The present invention has been made in an effort to provide a piezoelectric vibration module that generates vertical parallel movement through piezoelectric elements that are segmented in the longitudinal direction.

According to a first preferred embodiment of the present invention, there is provided a piezoelectric vibration module, including: a vibration plate with a flat lower plate; and piezoelectric elements placed symmetrically in the longitudinal direction around the center of a lower plate and generating vibration force by repetitively extending and being shrinkingly deformed through application of external power.

One or more piezoelectric elements may be placed on a left surface of the lower plate and one or more piezoelectric elements may be placed on a right surface of the lower plate around the center of the lower plate and the numbers of the piezoelectric elements to be placed on the left and right surfaces may be the same as each other.

The piezoelectric elements may synchronously extend or shrink to ensure stable vibration force.

The piezoelectric elements may have the same shape and the same size.

Two piezoelectric elements adjacent to the center of the lower plate may be in direct contact with each other on a center line.

The piezoelectric elements may be stacked in a single layer type or a multi-layer type.

The piezoelectric vibration module may further include: an upper case having a bottom surface opened and an inner space formed therein so that the vibration plate vibrates linearly; and a lower case coupled to the bottom surface of the upper case to shield the inner space of the upper case.

The vibration plate may further include: the lower plate; a pair of upper plates that stand vertically upward at the centers of both sides of the lower plate; and a weight body placed between the pair of upper plates in order to increase the vibration force of the piezoelectric element.

According to a second preferred embodiment of the present invention, there is provided a piezoelectric vibration module, including: a vibration plate with a flat lower plate; and piezoelectric elements placed symmetrically around the center of the lower plate and generating vibration force by repetitively extending and being shrinkingly deformed through application of external power and in particular, two piezoelectric elements adjacent to the center of the lower plate are spaced apart from each other at the same interval on the center line.

According to a third preferred embodiment of the present invention, there is provided a piezoelectric vibration module, including: a vibration plate with a flat lower plate; and three or more piezoelectric elements placed at the center of the lower plate and placed symmetrically around the center of the lower plate and generating vibration force by repetitively extending and being shrinkingly deformed through application of external power.

One or more piezoelectric elements may be placed on a left surface of the lower plate and one or more piezoelectric elements may be placed on a right surface of the lower plate around the center of the lower plate.

The piezoelectric elements may synchronously extend or shrink to ensure stable vibration force.

The piezoelectric elements may have the same shape and the same size.

The piezoelectric elements placed on the left surface of the lower plate and the piezoelectric elements placed on the right surface of the lower plate may be spaced apart from each other at the same interval.

The piezoelectric elements may be stacked in a single layer type or a multi-layer type.

The piezoelectric vibration module may further include: an upper case having a bottom surface opened and an inner space formed therein so that the vibration plate vibrates linearly; and a lower case coupled to the bottom surface of the upper case to shield the inner space of the upper case.

The vibration plate may further include: the lower plate; a pair of upper plates that stand vertically at the centers of both sides of the lower plate; and a weight body placed between the pair of upper plates in order to increase the vibration force of the piezoelectric element.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view of a piezoelectric vibration module according to a first preferred embodiment of the present invention;

FIG. 2 is an exploded perspective view of the piezoelectric vibration module illustrated in FIG. 1;

FIG. 3 is a front view of the piezoelectric vibration module according to the first preferred embodiment of the present invention except for an upper case;

FIGS. 4A to 4C are diagrams illustrating a driving process of the piezoelectric vibration module illustrated in FIG. 3;

FIG. 5 is a front view of a piezoelectric vibration module according to a second preferred embodiment of the present invention except for an upper case; and

FIG. 6 is a front view of a piezoelectric vibration module according to a third preferred embodiment of the present invention except for an upper case.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

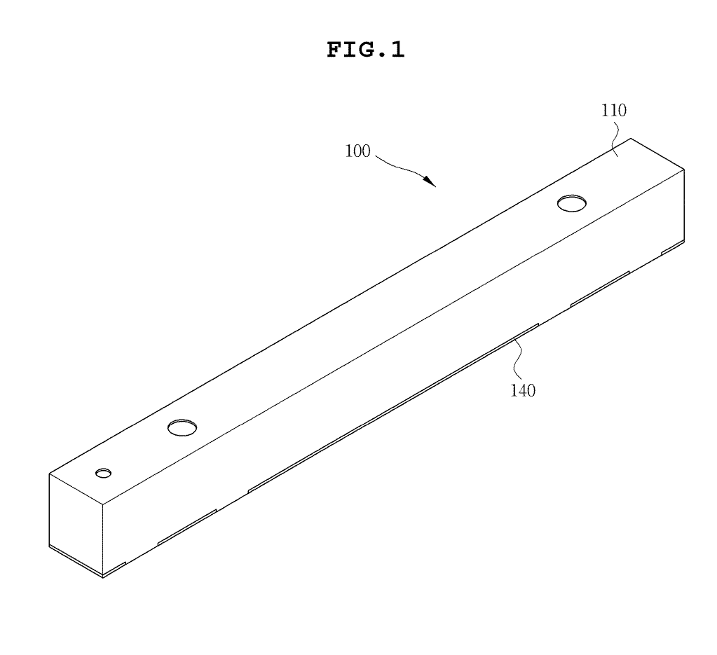

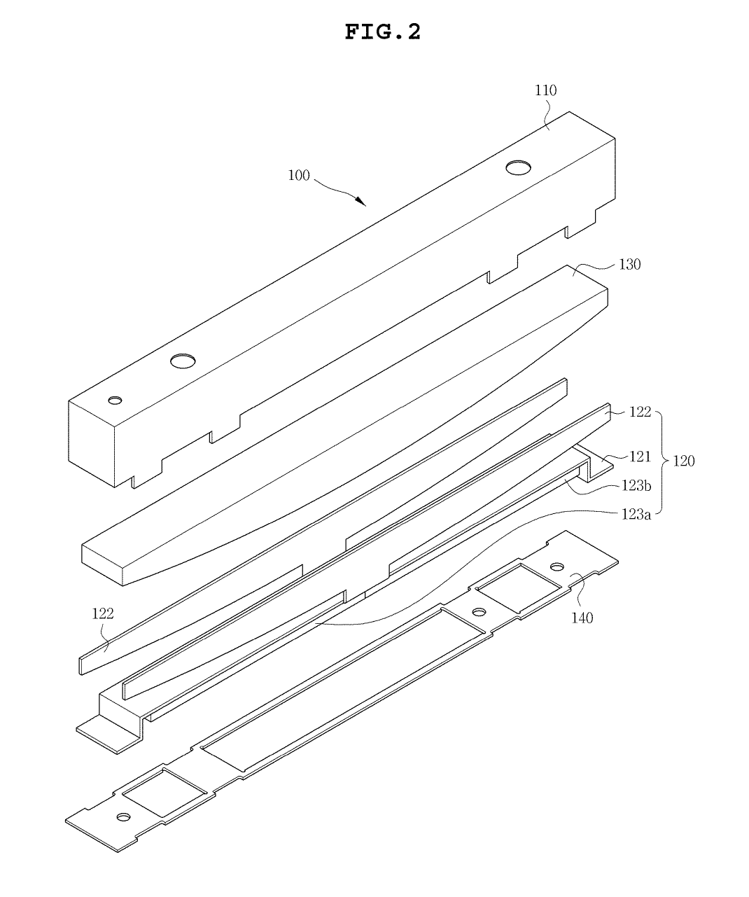

FIG. 1 is a perspective view of a piezoelectric vibration module according to a first preferred embodiment of the present invention and FIG. 2 is an exploded perspective view of the piezoelectric vibration module illustrated in FIG. 1.

As illustrated in the figures, the piezoelectric vibration module 100 according to the first preferred embodiment of the present invention includes an upper case 110, a vibration plate 120, a weight body 130, and a lower case 140. The piezoelectric vibration module 100 is used as a means for transferring vibration force to a touch screen panel (not illustrated).

The upper case 110 has a box shape in which one surface is opened and receives the vibration plate 120 mounted with piezoelectric elements 123a and 123b in an inner space thereof

The vibration plate 120 transfers vibration force of the piezoelectric elements 123a and 123b to external components through repetition of extension and shrinkage deformation integrally with the piezoelectric elements 123a and 123b as described above and includes a generally flat lower plate 121. Particularly, two or more piezoelectric elements 123a and 123b are mounted on one surface of the lower plate 121 and the weight body 130 is mounted on the other surface of the lower plate 121. The vibration plate 120 may include a printed circuit board (PCB) (not illustrated) that applies power for driving the piezoelectric elements 123a and 123b.

Alternatively, the vibration plate 120 may include a pair of upper plates 122 that are formed vertically upward on both sides of the lower plate 121 together with the flat lower plate 121 as described above. The upper plate 122 is coupled to the center of the lower plate 121. Each of the lower plate 121 and the upper plate 122 may be formed by a single integral component and may be fixedly coupled by various bonding methods unlike the above.

The vibration plate 120 is made of a metallic material having elastic force, for example, SUS to be transformed integrally with the piezoelectric elements 123a and 123b which repeatedly extend or is shrinkingly deformed according to application of external power. When the vibration plate 120 and the piezoelectric elements 123a and 123b are coupled to each other by the bonding coupling method, the vibration plate 120 may be made of invar which is a material having a similar thermal expansion coefficient as the piezoelectric element so as to prevent a bending phenomenon which may occur by hardening of a bonding member.

As described above, the vibration plate 120 is made of invar having the similar thermal expansion coefficient as the piezoelectric elements 123a and 123b, such that thermal stress is reduced, which is generated when the piezoelectric elements 123a and 123b operates or is subjected to thermal shock even under a high-temperature external environment, thereby preventing a piezoelectric deterioration phenomenon in which an electric characteristic deteriorates.

The pair of upper plates 122 are arranged in parallel to each other as large as for example, the width of the lower plate 121, and as a result, the weight body 130 may be placed between the pair of upper plates 122. The weight body 130 as a medium that maximally increases vibration force is inclined upward toward both ends from the center of the weight body 130 in order to prevent contact with the lower plate 121 of the vibration plate 120. As described above, in a structure in which the vibration plate 120 includes the upper plate 122, since the weight body 130 does not contact the lower plate 121 the piezoelectric elements 123a and 123b may be arranged on one surface of both flat surfaces of the lower plate 121.

For reference, the weight body 130 may be made of the metallic material and the weight body 130 is preferably made of a tungsten material having relatively high density in the same volume.

The lower case 140 is formed by a generally elongated planar plate. In this case, the lower case 140 has a size to close the opened bottom surface of the upper case 110.

The upper case 110 and the lower case 140 may be coupled to each other in various methods such as caulking, welding, and bonding which have already widely been known to those skilled in the art.

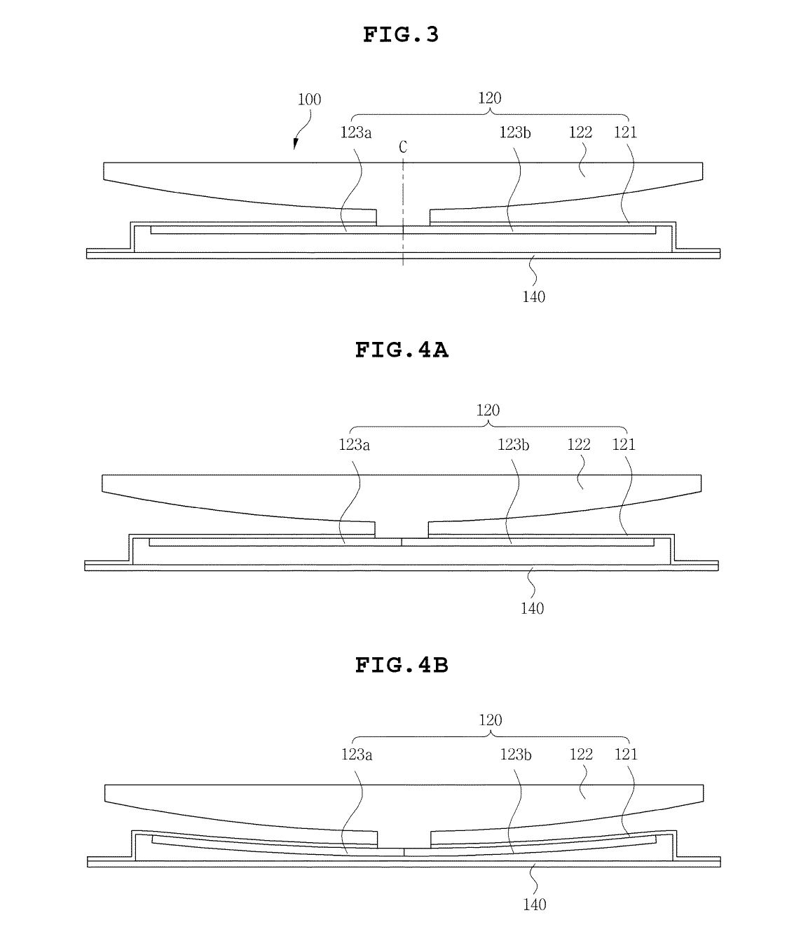

FIG. 3 is a front view of the piezoelectric vibration module according to the first preferred embodiment of the present invention except for an upper case.

The vibration plate 120 is spaced apart from the lower case 140 in parallel with a predetermined gap. Preferably, the lower plate 121 is coupled and fixed to both ends of the lower case 140 through steps formed at both ends thereof

Unlike the above, the lower case 140 includes coupling ends (not illustrated) at both ends thereof and both ends of the flat lower plate 121 are seated on two coupling ends of the lower case 140 to form a space by allowing the lower plate 121 of the vibration plate 120 and the lower case 140 to be spaced apart from each other.

Referring to FIG. 3, the piezoelectric vibration module 100 according to the first preferred embodiment of the present invention is formed in a symmetric structure around a virtual center line C at the center thereof

In particular, in the piezoelectric vibration module 100 according to the first preferred embodiment of the present invention, two piezoelectric elements 123a and 123b are arranged in series on one surface and/or the other surface of the lower plate 121 of the vibration plate 120 in the longitudinal direction. The piezoelectric vibration module 100 is not limited thereto and in the piezoelectric vibration module 100 according to the first preferred embodiment of the present invention, one or more piezoelectric elements are, in series, arranged on a left surface and a right surface on one flat surface of the lower plate 121 around the center line C.

The respective piezoelectric elements 123a and 123b have the same shape and extend toward both ends of the lower plate 121 from the center line C.

Since the spaced piezoelectric elements 123a and 123b of the present invention are arranged similarly around the center line C, the spaced piezoelectric elements 123a and 123b may create the same effect as the integrated piezoelectric element in the related art.

When power is applied to the respective piezoelectric elements 123a and 123b, the piezoelectric elements 123a and 123b are fully attached to the lower plate 121, such that a moment occurs around the center line C through extension and/or shrinkage. Since the movement occurs while the lower plate 121 is fixed to both ends of the lower case 140, the center of the vibration plate 120 is deformed vertically.

Moreover, the respective piezoelectric elements 123a and 123b may be configured to be stacked in a single-layer type or a multi-layer type. The piezoelectric element stacked in the multi-layer type may ensure an electric field required to drive the piezoelectric element at lower external voltage. Therefore, driving voltage of the piezoelectric vibration module 100 according to the present invention may be lowered, and as a result, in the present invention, the piezoelectric elements stacked in the multi-layer type are preferably adopted.

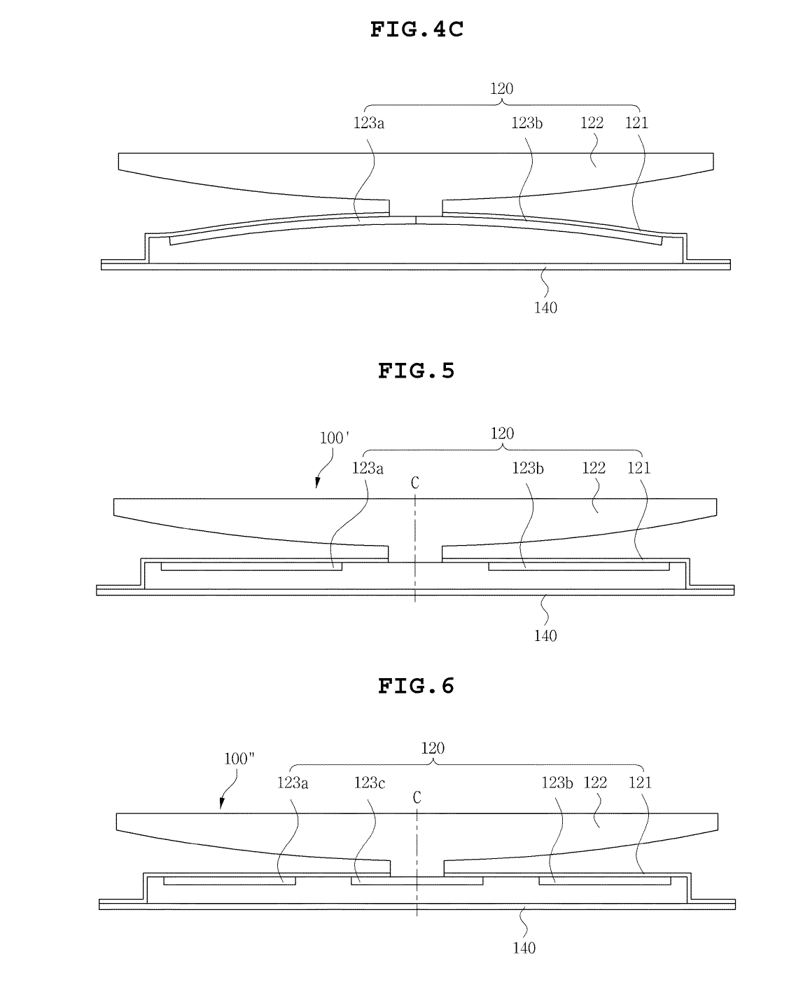

FIGS. 4A to 4C are diagrams illustrating a driving process of the piezoelectric vibration module 100 illustrated in FIG. 3. The piezoelectric vibration module 100 according to the first preferred embodiment of the present invention is coupled to an image display unit such as a touch screen panel or an LCD to transfer vibration force to the outside.

FIG. 4A is a front view of the piezoelectric vibration module 100 illustrating a state before external power is applied. FIG. 4B is a front view of the piezoelectric vibration module 100 in which the lengths of the piezoelectric elements 123a and 123b is increased when power is applied.

When the lengths of the piezoelectric elements 123a and 123b increases, deformation rate of the lower plate 121 is relatively small and the lower plate 121 is fixed to the lower case 140, and as a result, the vibration plate 120 is bent and driven downward. Contrary to this, FIG. 4C is a front view of the piezoelectric vibration module 100 in which the lengths of the piezoelectric elements 123a and 123b are decreased when power is applied. When the lengths of the piezoelectric elements 123a and 123b decrease, the lower plate 121 is bent and driven upward.

As illustrated in the figure, a user of a haptic device with the piezoelectric elements 123a and 123b divided into two or more may sense vibration feedback by vertical vibration.

FIG. 5 is a front view of a piezoelectric vibration module 100′ according to a second preferred embodiment of the present invention except for an upper case. The piezoelectric vibration module according to the second preferred embodiment of the present invention illustrated in FIG. 5 is similar as the piezoelectric vibration module 100 according to the first preferred embodiment of the present invention illustrated in FIG. 3 except for an arrangement state of the piezoelectric elements 123a and 123b. Similar or the same constituent members will not be herein excluded in order to help clear understanding of the present invention.

As illustrated in FIG. 5, in a piezoelectric vibration module 100′ according to a second preferred embodiment of the present invention, the respective piezoelectric elements 123a and 123b are mounted on the lower plate 121 with the respective piezoelectric elements 123a and 123b spaced apart from each other toward both ends of the lower plate 121 from the center line C at the same interval around the center line C at the center of the vibration plate 120.

Preferably, the respective piezoelectric elements 123a and 123b have the same shape and synchronously extend and/or shrink to allow stable vibration to be generated on the vibration plate 121.

Alternatively, in FIG. 5, one piezoelectric element 123a is placed on the flat left surface of the lower plate 121 and one piezoelectric element 123b is placed on the flat right surface of the lower plate 121 around the center line C, but are not limited thereto and one or more piezoelectric elements are placed on the left surface of the lower plate 121, whereas one or more piezoelectric elements may be placed on the right surface of the lower plate 121 similarly as above.

FIG. 6 is a front view of a piezoelectric vibration module 100″ according to a third preferred embodiment of the present invention except for an upper case. The piezoelectric vibration module according to the third preferred embodiment of the present invention illustrated in FIG. 6 is similar as the piezoelectric vibration module 100 according to the first preferred embodiment of the present invention illustrated in FIG. 3 except for an arrangement state of the piezoelectric elements 123a and 123b. Similar or the same constituent members will not be herein excluded in order to help clear understanding of the present invention.

As illustrated in FIG. 6, in a piezoelectric vibration module 100″ according to a third preferred embodiment of the present invention, a piezoelectric element 123c is placed at the center of the vibration plate 120 and the respective piezoelectric elements 123a and 123b are mounted on the lower plate 121 with the respective piezoelectric elements 123a and 123b spaced apart from each other toward both ends of the lower plate 121 from the center line C at the same interval around the center line C. In the piezoelectric vibration module 100″ according to the third preferred embodiment of the present invention, the piezoelectric elements 123a 123b, and 123c are all arranged on the straight line (longitudinal direction) with the piezoelectric elements 123a 123b, and 123c spaced apart from each other at a predetermined interval, but the respective piezoelectric elements 123a 123b, and 123c may be arranged so that the respective piezoelectric elements 123a, 123b, and 123c are in direct contact with the adjacent piezoelectric elements.

When power is applied to the piezoelectric elements 123a, 123b, and 123c, the piezoelectric elements 123a, 123b, and 123c synchronously extend and/or shrink to allow stable vibration to be generated on the vibration plate 120. The piezoelectric elements 123a and 123b to be placed on the left surface and the right surface of the lower plate 121 have the same size and shape so that the same deformation rate is provided from the left and right.

Alternatively, in FIG. 6, one piezoelectric element 123a is placed on the left surface of the lower plate 121 and one piezoelectric element 123b is placed on the right surface of the lower plate 121 around the center line C, but are not limited thereto and one or more piezoelectric elements are placed on the left surface of the lower plate 121, whereas one or more piezoelectric elements may be placed on the right surface of the lower plate 121 similarly as above.

According to the preferred embodiments of the present invention, there is provided the piezoelectric vibration module in which two or more piezoelectric elements are symmetrically arranged on the straight line on one surface of the vibration plate.

Durability can be improved by reducing the length through comparison with the width of a planar piezoelectric element.

The present invention can applied without modifying the piezoelectric vibration module in the related art, work manpower depending on a structural change can be remarkably reduced.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A piezoelectric vibration module, comprising:
a vibration plate with a flat lower plate; and
piezoelectric elements placed symmetrically in the longitudinal direction around the center of a lower plate and generating vibration force by repetitively extending and being shrinkingly deformed through application of external power.

2. The piezoelectric vibration module as set forth in claim 1, wherein one or more piezoelectric elements are placed on a left surface of the lower plate and one or more piezoelectric elements are placed on a right surface of the lower plate around the center of the lower plate.

3. The piezoelectric vibration module as set forth in claim 1, wherein two piezoelectric elements adjacent to the center of the lower plate are in direct contact with each other on a center line.

4. The piezoelectric vibration module as set forth in claim 1, wherein two piezoelectric elements adjacent to the center of the lower plate is spaced apart from each other at the same interval on the center line.

5. The piezoelectric vibration module as set forth in claim 4, wherein the piezoelectric element is additionally placed at the center of the lower plate.

6. The piezoelectric vibration module as set forth in claim 1, wherein one or more piezoelectric elements placed on the left surface of the lower plate and one or more piezoelectric elements placed on the right surface of the lower plate are spaced apart from each other at the same interval.

7. The piezoelectric vibration module as set forth in claim 1, wherein the piezoelectric elements synchronously extend or shrink.

8. The piezoelectric vibration module as set forth in claim 1, wherein the piezoelectric elements have the same shape and the same size.

9. The piezoelectric vibration module as set forth in claim 1, wherein the piezoelectric elements are stacked in a single layer type or a multi-layer type.

10. The piezoelectric vibration module as set forth in claim 1, further comprising:
an upper case having a bottom surface opened and an inner space formed therein so that the vibration plate vibrates linearly; and
a lower case coupled to the bottom surface of the upper case to shield the inner space of the upper case.

11. The piezoelectric vibration module as set forth in claim 1, wherein the vibration plate further includes the lower plate; a pair of upper plates that stand vertically upward at the centers of both sides of the lower plate; and a weight body placed between the pair of upper plates in order to increase the vibration force of the piezoelectric element.
